(19) United States
(12) Patent Application Publication
(10) Pub. No.: US 2016/0120063 A1
(43) Pub. Date: Apr. 28, 2016

(54) LIQUID COOLING SYSTEM HAVING HEAT DISSIPATION FINS THEREIN

(71) Applicant: Foxconn Technology Co., Ltd., New Taipei (TW)

(72) Inventors: NIEN-TIEN CHENG, New Taipei (TW); WEI-HANG HSU, New Taipei (TW)

(21) Appl. No.: 14/568,839

(22) Filed: Dec. 12, 2014

(30) Foreign Application Priority Data
Oct. 24, 2014 (CN) 201410574204.6

(51) Int. Cl. H05K 7/20

(52) U.S. Cl. CPC H05K 7/20254; H05K 7/20272

(57) ABSTRACT

A liquid cooling system includes a liquid cooling radiator, a circulation device, and a plurality of circulation pipes coupling the circulation device with the liquid cooling radiator. A liquid circulation channel is defined in the liquid cooling radiator. A plurality of heat dissipation fins are arranged in the liquid circulation channel. The circulation device drives a liquid coolant through the liquid cooling radiator via the liquid circulation channel to make a heat exchange circulation.

### FIELD

The subject matter herein generally relates to a cooling system for a heat generating module, especially to a liquid cooling system having a plurality of heat dissipation fins therein.

### BACKGROUND

During the operation of an electric products (computers, notebooks or touch pads), chips, such as CPU, GPU produces heat. Heat has to be quickly carried away from the chips during the operation. Excessively high temperature causes the chips unable to work normally. Various cooling means, such as cooling system, have been developed for dissipating heat from the chips of an electric product.

### BRIEF DESCRIPTION OF THE DRAWINGS

Implementations of the present technology will now be described, by way of example only, with reference to the attached figures.

FIG. 1 is an isometric view of a liquid cooling system for a heat generating module in accordance with a first embodiment of the present disclosure.

FIG. 2 is an exploded view of the liquid cooling system of FIG. 1.

FIG. 3 is an exploded view of a liquid cooling system in accordance with a second embodiment of the present disclosure.

FIG. 4 is an exploded view of a liquid cooling system in accordance with a third embodiment of the present disclosure.

FIG. 5 is an exploded view of a liquid cooling system in accordance with a fourth embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

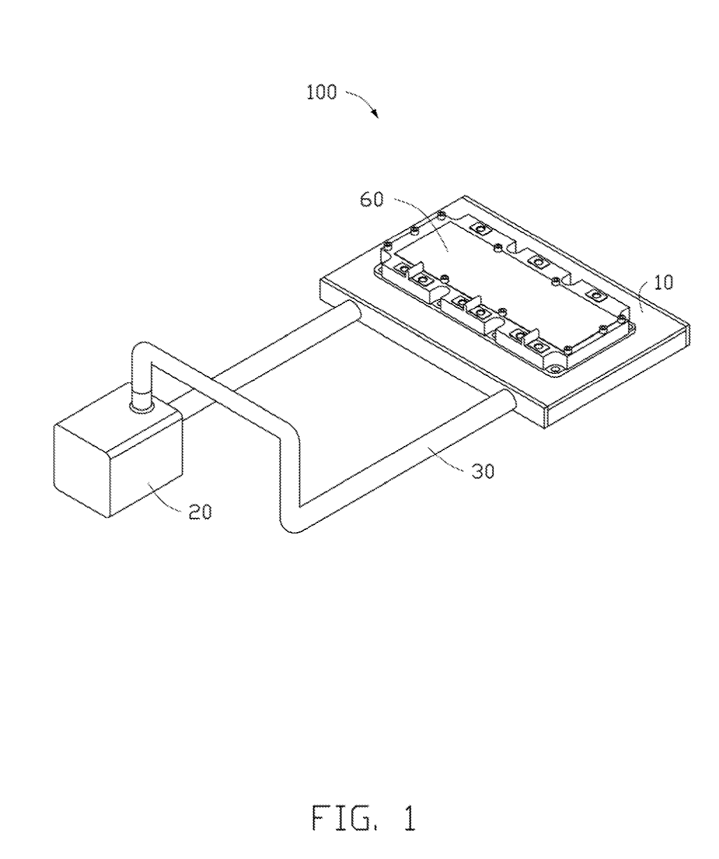

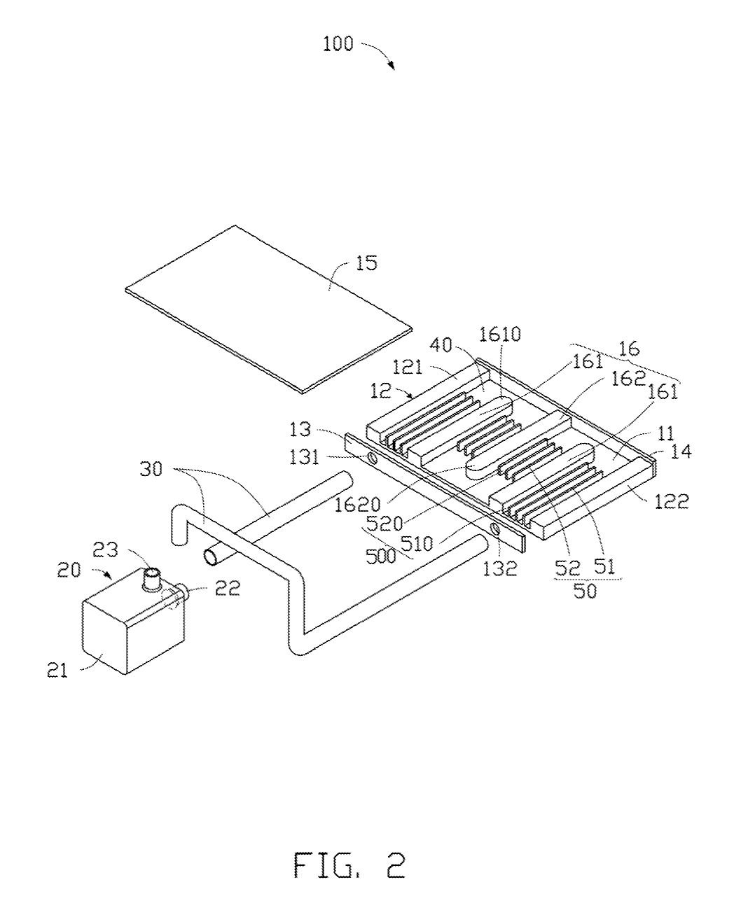

FIG. 1 illustrates a liquid cooling system 100 in accordance with the first embodiment of the present disclosure. The liquid cooling system 100 for a heat generating module 60 has a liquid cooling radiator 10, a circulation device 20 and two circulation pipes 30 coupling the liquid cooling radiator 10 with the circulation device 20. Referring to FIG. 2, a liquid circulation channel 40 is defined in the liquid cooling radiator 10. A plurality of heat dissipation fins 50 are arranged in the liquid circulation channel 40. The circulation device 20 drives a liquid coolant through the liquid cooling system 100 to make a heat exchange circulation, and to effectively reduce the working temperature of a heat generating module 60.

The liquid cooling radiator 10 is made of material with high heat conductivity, such as copper or aluminum. The heat generating module 60 may be an Insulated Gage Bipolar Translator (IGBT) module. In at least one embodiment, the coolant may be water, alcohol or air.

In this embodiment, the liquid cooling radiator 10 has a bottom plate 11, two side walls 12 extending from opposite sides of the bottom plate 11, a front wall 13, a back wall 14 and a top cover 15 supported by the side walls 12, the front wall 13 and the back wall 14.

The side wall 12 includes a first side wall 121 and a second side wall 122. The first side wall 121 and the second side wall 122 extend from opposite edges of the bottom plate 11 respectively. Preferably, the first side wall 121 and the second side wall 122 vertically and upwardly extend from the bottom plate 11. The first side wall 121 is parallel with the second side wall 122. The first side wall 121 and the second side wall 122 can be formed with the bottom plate 11 as a single piece.

The front wall 13 and the back wall 14 are rectangular plates. The front wall 13 and the back wall 14 are located at opposite ends of the first side wall 121 and the second side wall 122 to attach the first side wall 121 and the second side wall 122. Preferably, height of the first side wall 121 or the second side wall 122 equals that of the front wall 13 or the back wall 14. Alternatively, the front wall 13 and the back wall 14 can be formed with the bottom plate 11 as a single piece.

The top cover 15 is a plan plate and the top cover 15 can be formed with the bottom plate 11, the side walls 12, the front wall 13 and the back wall 14 as a single piece. In top cover 15, the bottom plate 11, the side walls 12, the front wall 13 and the back wall 14 corporately defines a sealed spaced. In this embodiment, outer surfaces of the top cover 15 are configured to contact the heat generating module 60.

The liquid cooling radiator 10 further includes a plurality of partition boards 16. The partition boards 16 define the liquid circulation channel 40. The partition boards 16 are arranged between the first side wall 121 and the second side wall 122. The partition boards 16 are spaced from the first side wall 121 and the second side wall 122. In at least one embodiment, the liquid circulation channel 40 is a winding channel. In this embodiment, the liquid circulation channel 40 is “S” shaped.

Each partition board 16 includes a first partition board 161 and a second partition board 162. The first partition board 161 is spaced from the second partition board 162. Preferably, the first partition board 161 is parallel with the second partition board 162. In at least one embodiment, the first partition board 161 and the second partition board 162 are parallel with the side walls 12.

The first partition board 161 extends from a front edge of the bottom plate 11 to a back edge of the bottom plate 11. An outer end 1610 of the first partition board 161 is spaced from the back wall 14. Preferably, the outer end 1610 of the first partition board 161 has a semi-circular configuration which helps guide coolant to flow through the liquid circulation channel 40.

The second partition board 162 extends from the back edge of the bottom plate 11 to the front edge of the bottom plate 11, and an outer end 1620 of the second partition board 162 is spaced from the front wall 13. Preferably, the outer end 1620 of the second partition board 162 has a semi-circular configuration which helps guide coolant to flow through the liquid circulation channel 40.

In the first embodiment, the partition board 16 has two first partition boards 161 and a second partition board 162. The two first partition boards 161 are located between the first side wall 121 and the second side wall 122, and the second partition board 162 is located between the two first partition boards 161.

A flowing channel 500 is defined by a plurality of heat dissipation fins 50. The heat dissipation fins 50 are parallel with the liquid circulation channel 40. The heat dissipation fins 50 can be formed with the bottom plate 11 as a single piece. The heat dissipation fins 50 include a plurality of first fins 51 and a plurality of second fins 52 with different sizes.

The first fins 51 are formed between the first side wall 121 and the first partition board 161, and are formed between the second side wall 122 and the first partition board 161. The first fins 51 vertically and upwardly extend from a top surface of the bottom plate 11. The height of the first fins 51 equal that of the first side wall 121 and that of the first partition boards 161. The first fins 51 extend from the front edge of the bottom plate 11 toward the back edge of the bottom plate 11, and the length of each first fin 51 is less than that of the first partition board 161.

The second fins 52 are formed between the first partition board 161 and the second partition board 162. The length of each second fin 52 is less than that of each first fin 51. The second fins 52 are located at a central portion of the bottom plate 11. In at least one embodiment, back ends of the second fins 52 adjacent to the back wall 14 are coplanar with back ends of the first fins 51 adjacent to the back wall 14.

The flowing channel 500 has a plurality of first flowing channel 510 between neighboring first fins 51 and a plurality of second flowing channel 520 between neighboring second fins 52. The first flowing channels 510 are parallel with the second flowing channels 520. Preferably, the width of the first flowing channel 510 is less than that of the second flowing channel 520. In at least one embodiment, the width of each first flowing channel 510 equals that of the second flowing channel 520.

The front wall 13 of the liquid cooling radiator 10 has a liquid input port 131 and a liquid output port 132. The liquid input port 131 and the liquid output 132 are corresponding with the first flowing channels 510 defined by the first fins 51. The liquid input port 131 is spaced from the liquid output port 132. The liquid input port 131 and the liquid output port 132 are coupled with opposite ends of the liquid circulation channel 40 respectively. Coolant flows into the liquid cooling radiator 10 from the liquid input port 131, which flows along the liquid circulation channel 40, and then flows out from the liquid output port 132.

The circulation device 20 can be a pump. The circulation device 20 has a main body 21, an output port 22 and an input port 23. The output port 22 is coupled with the liquid input port 131 in the front wall 13. The input port 23 is coupled with the liquid output port 132 in the front wall 13. In this embodiment, the circulation pipe 30 couples the output port 22 to the liquid input port 131 of the front wall 13, and couples the input port 23 to the liquid output 132 in the front wall 13.

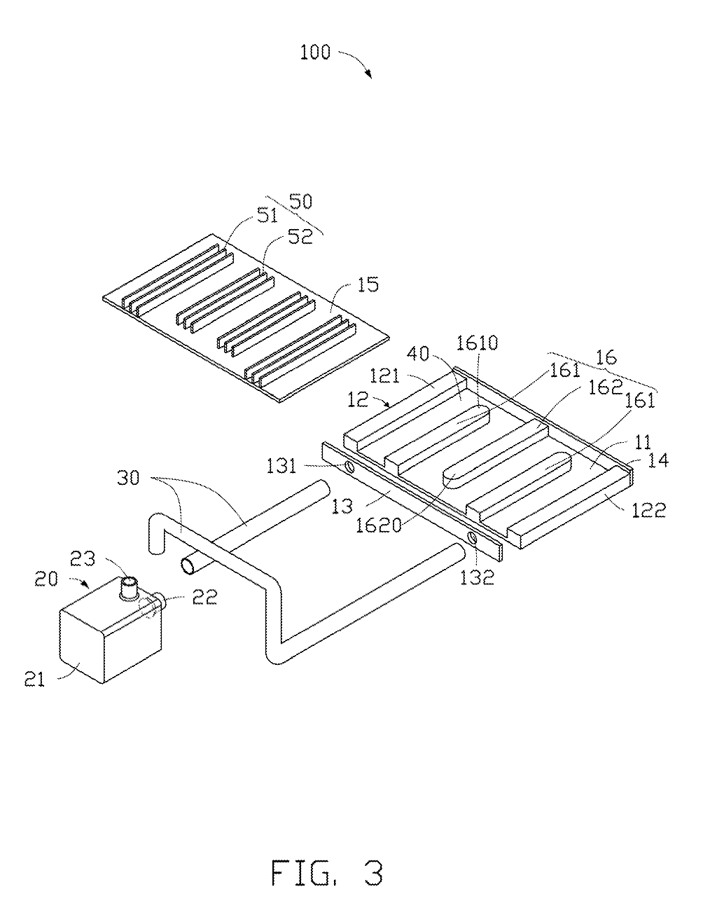

FIG. 3 illustrates a liquid cooling system 100 in accordance with a second embodiment of the present disclosure. In this embodiment, the heat dissipation fins 50 are formed on inner surface of the top cover 15. When the top cover 15 covers the space defined by the bottom plate 11, the side walls 12, the front wall 13 and the back wall 14, the first fins 51 are arranged between the first side wall 121 or the second side wall 122 and the first partition board 161. The second fins 52 are arranged between the first partition board 161 and the second partition board 162.

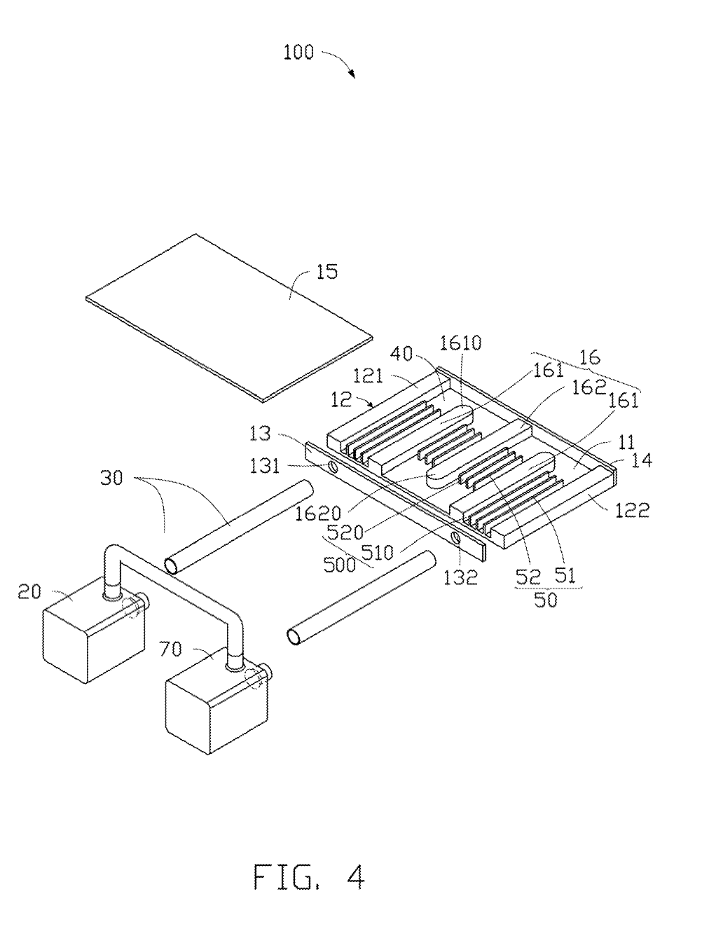

FIG. 4 illustrates a liquid cooling system 100 in accordance with a third embodiment of the present disclosure. In this embodiment, the liquid cooling system 100 further has a heat exchange device 70. The heat exchange device 70 reduces the temperature of the coolant from the liquid output port 132 in the front wall 13 of the liquid cooling radiator 10 before the high temperature coolant is bumped into the liquid cooling radiator 10 again. The heat exchange device 70 can have a fan or a heat pipe which helps reduce the temperature of the coolant. In at least one embodiment, the heat exchange device 70 is coupled between the circulation device 20 and the liquid cooling radiator 10.

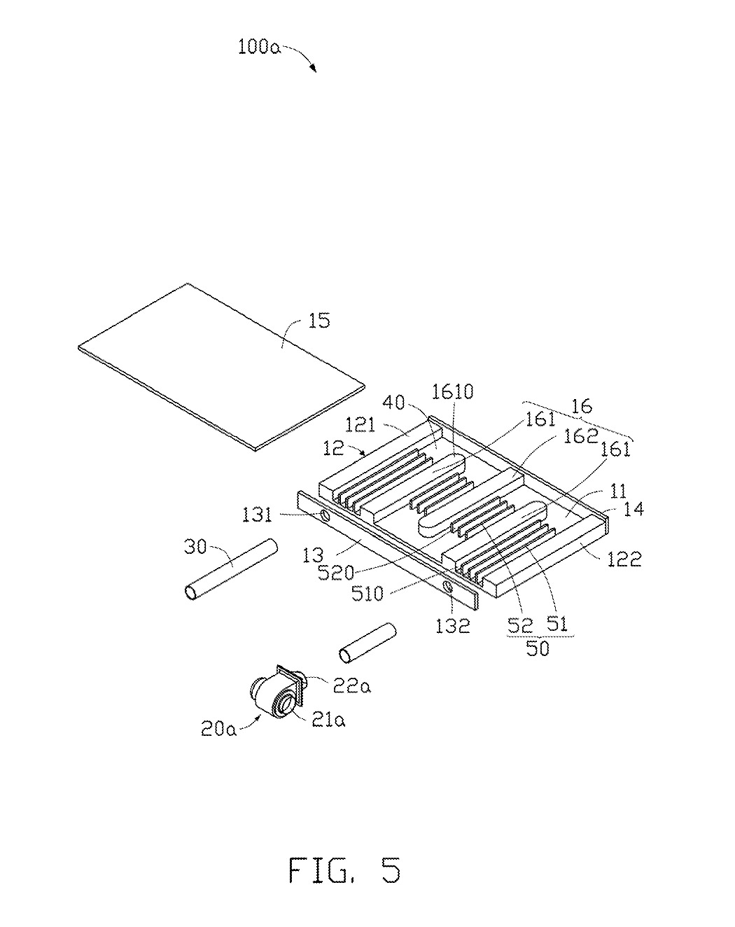

FIG. 5 illustrates another liquid cooling system 100 in accordance with a fourth embodiment. In this embodiment, the circulation device 20a can be a blower. The circulation device 20a has an air input port 21a and an air output port 22a. The circulation device 20a absorbs air via the air input port 21a, and blows the air into the liquid cooling system 100 from the liquid input port 131. And then, the air flows through the liquid circulation channel 40 to output from the liquid output port 132 to dissipate heat from the heat generating module 60.

The embodiments shown and described above are only examples. Many details are often found in the art such as the other features of a liquid cooling system. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A liquid cooling system, comprising:
a liquid cooling radiator;
a circulation device; and
a plurality of circulation pipes coupling the circulation device with the liquid cooling radiator, wherein a liquid circulation channel is defined in the liquid cooling radiator, a plurality of heat dissipation fins are arranged in the liquid circulation channel, and the circulation device drives a liquid coolant through the liquid cooling radiator to make a heat exchange circulation.

2. The liquid cooling system of claim 1, wherein the heat dissipation fins are parallel with the liquid circulation channel.

3. The liquid cooling system of claim 2, wherein the heat dissipation fins comprises a plurality of first fins and a plurality of second fins with different sizes.

4. The liquid cooling system of claim 3, wherein the second fins are located between the first fins.

5. The liquid cooling system of claim 4, wherein a first flowing channel is defined between neighboring first fins, and a second flowing channel is defined between neighboring second fins, and the width of the first flowing channel is less than that of the second flowing channel.

6. The liquid cooling system of claim 5, wherein the liquid cooling radiator has a liquid input port and a liquid output port corresponding with the first flowing channels respectively.

7. The liquid cooling system of claim 1, wherein a plurality of partition boards are formed in the liquid cooling radiator to define the liquid circulation channel.

8. The liquid cooling system of claim 7, wherein outer ends of the partition boards have semicircular configurations.

9. The liquid cooling system of claim 1, wherein the liquid cooling radiator has a bottom plate, side walls extends from the bottom plate, a front wall and a back wall attached to the side walls respectively, and a top cover, the heat dissipation fins upwardly extends from the bottom plate.

10. The liquid cooling system of claim 9, wherein further comprising a plurality of partition boards formed on the bottom plate and between side walls to define the liquid circulation channel.

11. The liquid cooling system of claim 10, wherein outer ends of the partition boards have semicircular configurations.

12. The liquid cooling system of claim 10, wherein the partition board has two first partition boards and a second partition board spaced from the first partition boards, the second partition board is between the two first partition boards.

13. The liquid cooling system of claim 12, wherein heat dissipation fins have plural first fins and plural second fins with different sizes, the first fins are located between the side walls and the first partition board, and the second fins are located between the first partition board and the second partition board.

14. The liquid cooling system of claim 13, wherein wideness of each first flowing channel defined between neighboring first fin is less than that of each second flowing channel defined between neighboring second fins.

15. The liquid cooling system of claim 14, wherein a liquid input port and a liquid output port are defined in front wall of the liquid cooling radiator, which are corresponding with the first flowing channels defined by the first fins respectively.

16. The liquid cooling system of claim 1, wherein the circulation device is a bump.

17. The liquid cooling system of claim 1, wherein the circulation device is a blower.

18. The liquid cooling system of claim 1, wherein further comprising a heat exchange device coupled between the circulation device and the liquid cooling radiator to reduce the temperature of coolant in circulation.

19. The liquid cooling system of claim 1, wherein the liquid circulation channel is S shaped.

20. A liquid cooling system, comprising:
a liquid cooling radiator;
a circulation device; and
a plurality of circulation pipes coupling the circulation device with the liquid cooling radiator, wherein a plurality of heat dissipation fins are formed in a liquid circulation channel of the liquid cooling radiator, the heat dissipation fins have first fins and second fins, the width of first flowing channels defined by neighboring first fins is less than that of second flowing channels defined by neighboring second fins, the first flowing channels are corresponding with a liquid input port and a liquid output port of the liquid circulation channel respectively.
